(19) United States
(12) Patent Application Publication
(10) Pub. No.: US 2010/0330807 A1
(43) Pub. Date: Dec. 30, 2010

(54) SEMICONDUCTOR APPARATUS MANUFACTURING METHOD AND IMPRINT TEMPLATE

(76) Inventor: Yoshihito KOBAYASHI, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/781,067

(22) Filed: May 17, 2010

(30) Foreign Application Priority Data
Jun. 29, 2009 (JP) 2009-153946

(51) Int. Cl. H01L 21/302; B29C 59/02

(52) U.S. Cl. 438/689; 425/385; 257/E21.214

(57) ABSTRACT

A method for manufacturing a semiconductor apparatus, includes: supplying a first imprint material onto a dicing region surrounding each chip of a semiconductor wafer; bringing a first template having a frame-like configuration into contact with the first imprint material and curing the first imprint material; peeling the first template from the first imprint material to form a first pattern in the first imprint material after the curing of the first imprint material; supplying a second imprint material onto a chip region of the semiconductor wafer on an inner side of the first pattern; bringing a second template into contact with the second imprint material and curing the second imprint material; peeling the second template from the second imprint material to form a second pattern in the second imprint material after the curing of the second imprint material; etching the semiconductor wafer, the first imprint material having the first pattern and the second imprint material having the second pattern being used as a mask.

### CROSS-REFERENCE TO RELATED APPLICATIONS

This application is based upon and claims the benefit of priority from the prior Japanese Patent Application No. 2009-153946, filed on Jun. 29, 2009; the entire contents of which are incorporated herein by reference.

### BACKGROUND

### Field

Embodiments of the invention relate generally to a semiconductor apparatus manufacturing method and an imprint template.

During pattern formation by an imprinting method, fluctuation of the thickness and pattern configuration of the imprint material unfortunately occurs easily proximal to the edge portion of the template. Such problems are caused by the absence of a pattern to restrict or control the flow of the imprint material beyond the edge portion of the template. Normally, the template is formed corresponding to one chip; and pattern transfer is performed by a step-and-repeat method for each of the chips. Therefore, it can be said that the pattern precision tends to decline easily proximal to the chip outer edge.

JP-A 2007-19466 (Kokai) discusses performing a pattern transfer using a first template (mold) in an inner region of a semiconductor wafer after performing a pattern transfer in an outer circumferential region using a second template (mold). The outer circumferential region recited above is a wafer peripheral region at an edge portion of the wafer or proximal thereto. After the pattern formation in the wafer peripheral region, a pattern transfer is performed multiply using the first template (mold) in the inner region in which multiple chips are formed. Accordingly, in the inner region, the pattern transfer is performed with the first template using step-and-repeat for each of the chips. In such a case, as expected, fluctuation of the thickness and pattern configuration of the imprint material easily occurs proximally to the edge portion of the template corresponding to portions proximal to the chip outer edge; and there is a risk that the pattern precision may decrease proximally to the chip outer edge.

### SUMMARY

According to an aspect of the invention, there is provided a method for manufacturing a semiconductor apparatus, including: supplying a first imprint material onto a dicing region surrounding each chip of a semiconductor wafer; bringing a first template having a frame-like configuration into contact with the first imprint material and curing the first imprint material; peeling the first template from the first imprint material to form a first pattern in the first imprint material after the curing of the first imprint material; supplying a second imprint material onto a chip region of the semiconductor wafer on an inner side of the first pattern; bringing a second template into contact with the second imprint material and curing the second imprint material; peeling the second template from the second imprint material to form a second pattern in the second imprint material after the curing of the second imprint material; etching the semiconductor wafer, the first imprint material having the first pattern and the second imprint material having the second pattern being used as a mask.

According to another aspect of the invention, there is provided an imprint template, including: a first template having a frame-like pattern corresponding to a pattern of a dicing region surrounding each chip of a semiconductor wafer; and a second template having an inverted pattern of a recess/protrusion pattern, the recess/protrusion pattern being formed in a chip region of the semiconductor wafer on an inner side of the dicing region.

### BRIEF DESCRIPTION OF THE DRAWINGS

FIGS. 1A and 1B are schematic views of a first template in an imprint template according to an embodiment of the invention;

FIGS. 2A and 2B are schematic views of a second template in the imprint template;

FIGS. 3A to 4E are schematic cross-sectional views illustrating a method for manufacturing a semiconductor apparatus according to the embodiment of the invention;

FIG. 5 is a schematic plan view of a semiconductor wafer;

FIG. 6 is a schematic view of a first template in an imprint template according to another embodiment of the invention; and

FIGS. 7A and 7B are schematic cross-sectional views illustrating a method for manufacturing a semiconductor apparatus according to a comparative example.

### DETAILED DESCRIPTION

Embodiments of the invention will now be described with reference to the drawings.

A method for manufacturing a semiconductor apparatus according to an embodiment of the invention includes a process of forming a pattern by an imprinting method. The object of the pattern formation is a semiconductor wafer.

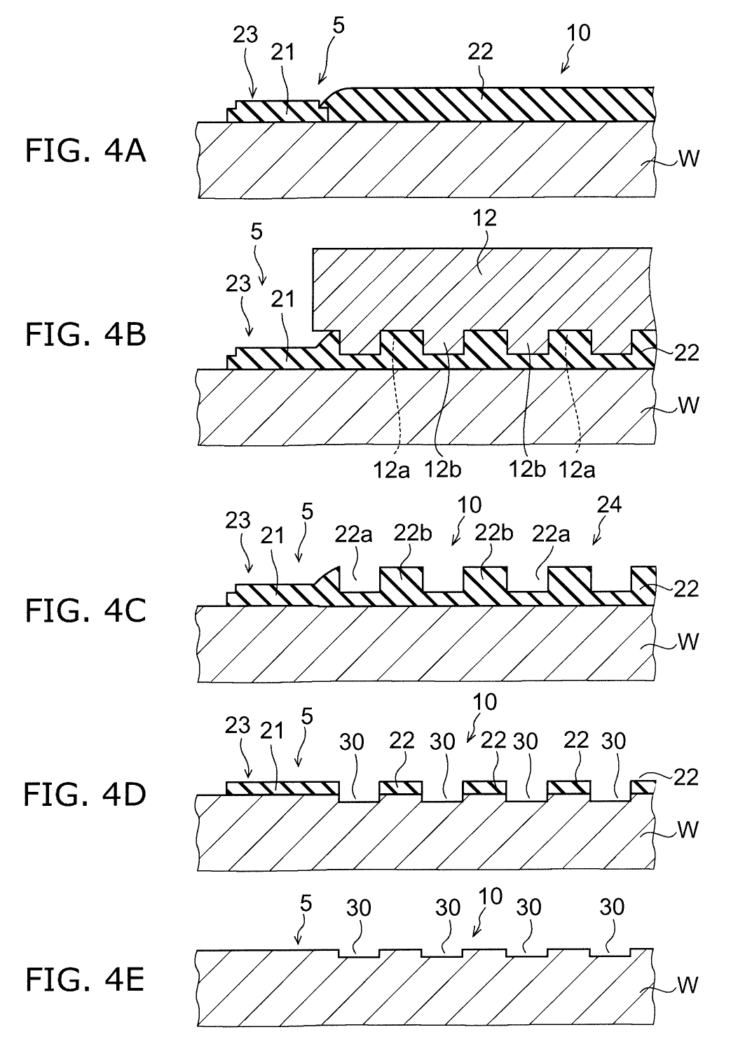

FIG. 5 is a schematic plan view of a semiconductor wafer W. Multiple semiconductor chips (also referred to herein simply as chips) C are formed in the semiconductor wafer W. Each of the chips C is partitioned from other chips C by a dicing line 50. After a series of wafer processes, dicing is performed to separate each of the chips C along the dicing line 50.

In this embodiment, two templates, i.e., a first template and a second template, are used as an imprint template.

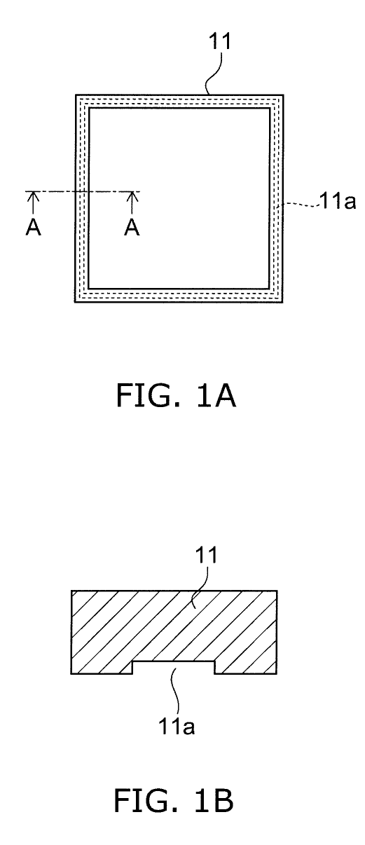

FIG. 1A is a schematic plan view of a first template 11. FIG. 1B is an enlarged cross-sectional view along line A-A of FIG. 1A.

The first template 11 is formed in a quadrilateral frame-like configuration. A recess 11a is made in the first template 11 with a size and a pattern layout corresponding to the dicing region (the regions in which the dicing line 50 is formed) surrounding each of the chips C. In other words, the recess 11a is formed in a quadrilateral frame-like configuration.

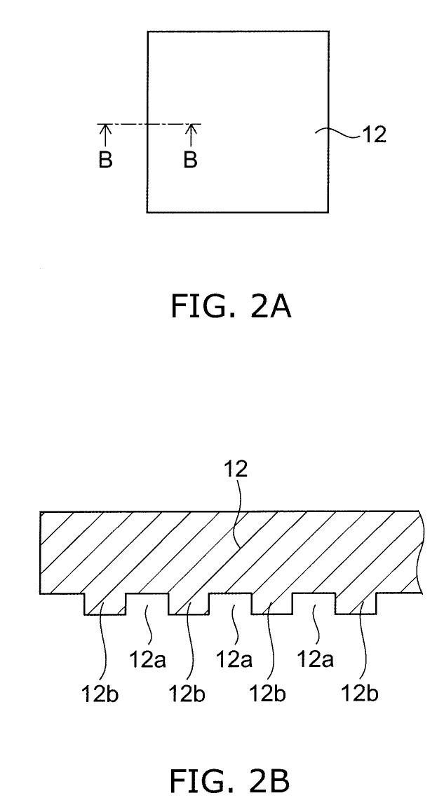

FIG. 2A is a schematic plan view of a second template 12. FIG. 2B is an enlarged cross-sectional view along line B-B of FIG. 2A.

The second template 12 is formed in a quadrilateral configuration. A recess/protrusion pattern made of a recess 12a and a protrusion 12b is formed on the second template 12. The recess/protrusion pattern is an inverted pattern of the pattern to be formed on the chips C and has the same pitch and size as the pattern to be formed on the chips C.

The outer dimensions of the second template 12 are slightly larger than the inner dimensions of the first template 11 so that the outer edge portion of the second template 12 slightly overlaps the inner edge portion of the first template 11 when the first template 11 and the second template 12 are overlaid on each other with centers aligned.

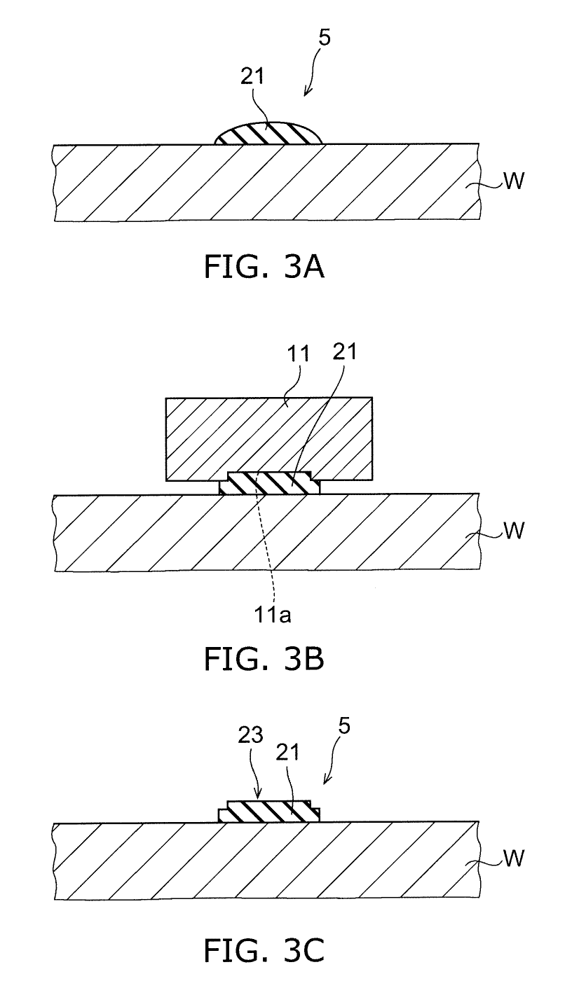

A pattern formation using the first template 11 and the second template 12 will now be described with reference to FIGS. 3A to 4E.

First, as illustrated in FIG. 3A, a first imprint material 21 is supplied onto a dicing region 5 of the semiconductor wafer W. The semiconductor wafer W is held by a not-illustrated holder. The first imprint material 21 may be dropped onto the dicing region 5 in a liquid or paste state, for example, from a nozzle by an inkjet method and the like. The first imprint material 21 is supplied in a frame-like configuration to match the layout pattern of the dicing region 5.

Then, as illustrated in FIG. 3B, the recess 11a of the first template 11 is pressed into contact with the first imprint material 21. The first template 11 is moved toward the semiconductor wafer W while being held by a not-illustrated holder.

The first imprint material 21 enters into the recess 11a when the recess 11a of the first template 11 is pressed onto the first imprint material 21. The first imprint material 21 is cured in this state. The first imprint material 21 is cured according to the characteristics of the first imprint material 21 by performing heating or ultraviolet irradiation.

After the curing of the first imprint material 21, the first template 11 is peeled from the first imprint material 21. Thereby, a first pattern 23 is formed in a protruding configuration in the first imprint material 21 in the dicing region 5 as illustrated in FIG. 3C. The first pattern 23 is formed in a quadrilateral frame-like configuration to match the dicing region 5 surrounding each of the chips C.

Then, as illustrated in FIG. 4A, a second imprint material 22 is supplied onto a chip region 10 on the inner side of the dicing region 5 in which the first pattern 23 is provided. The second imprint material 22 may be dropped onto the chip region 10 in a liquid or paste state, for example, from a nozzle by an inkjet method and the like.

The first imprint material 21 and the second imprint material 22 may include, for example, a photocurable resin such as urethane, epoxy, and acrylic resin. More specifically, examples include the low viscosity ultraviolet-curing resins HDDA (1,6-hexanediol-diacrylate) and HEBDM (bis(hydroxyethyl)bisphenol-A dimethacrylate). Alternatively, the first imprint material 21 and the second imprint material 22 may include a thermosetting resin such as phenol, epoxy, silicone, and polyimide or a thermoreversible resin such as poly-methyl methacrylate (PMMA), polycarbonate, and acrylic resin.

Then, as illustrated in FIG. 4B, a pattern portion of the second template 12 in which the recess 12a and the protrusion 12b are formed is pressed into contact with the second imprint material 22. The second template 12 is moved toward the semiconductor wafer W while being held by a not-illustrated holder.

Here, the thickness of the first pattern 23 formed in the first imprint material 21 is made thinner than the thickness of the second imprint material 22 supplied onto the chip region 10. Thereby, the second template 12 and the first pattern 23 do not interfere; tilting and position shifting of the second template 12 are prevented; and high precision pattern transfer can be performed.

As described above, it is necessary for the thickness of the first pattern 23 to be set so that the second template 12 and the first pattern 23 do not interfere when the second template 12 is pressed onto the second imprint material 22. However, the etching resistance of the first imprint material 21 is considered to ensure the necessary thickness as an etching mask and avoid the entire first pattern 23 being undesirably consumed during the etching described below. The supply amount and the thickness of the second imprint material 22 are set according to the pattern density, aspect ratio, etc., to be formed in the chip region 10.

The cured first pattern 23 already exists in a protruding configuration around the chip region 10 during the imprinting of the second imprint material 22. Accordingly, the first pattern 23 functions as a barrier to prevent the second imprint material 22 from flowing into chip regions other than the intended chip region 10. Thereby, fluctuation of the thickness of the second imprint material 22 proximal to the chip outer edge, the pattern configuration formed in the second imprint material 22, the size, and the like is suppressed; and pattern formation can be performed with good precision.

As described above, the first pattern 23 formed beforehand can stop the second imprint material 22 from flowing outside of the chip region 10. Therefore, it is unnecessary to restrict the supply amount of the second imprint material 22 proximal to the chip outer edge to suppress the flow of the second imprint material 22. Thereby, undesirable gaps proximal to the chip outer edge due to an insufficient supply amount of the second imprint material 22 can be avoided.

As illustrated in FIG. 4B, the second imprint material 22 is cured in the state in which the second template 12 is pressed onto the second imprint material 22. The second imprint material 22 is cured by performing heating or ultraviolet irradiation according to the characteristics of the second imprint material 22.

After the curing of the second imprint material 22, the second template 12 is peeled from the second imprint material 22. Thereby, as illustrated in FIG. 4C, a second pattern 24 is formed with the second imprint material 22 in the chip region 10. The second pattern 24 has a recess 22a and a protrusion 22b. The recess 22a is an inverted pattern of the protrusion 12b formed on the second template 12. The protrusion 22b is an inverted pattern of the recess 12a made in the second template 12.

Then, etching of the semiconductor wafer W is performed using a mask of the first imprint material 21 having the first pattern 23 and the second imprint material 22 having the second pattern 24. The state after such etching is illustrated in FIG. 4D.

By such etching, all of the second imprint material 22 below the recess 22a of the second pattern 24 is consumed; the semiconductor wafer W therebelow is exposed and etched; and a recess 30 is made in the surface of the semiconductor wafer W. During the etching of the semiconductor wafer W, insulating layers, semiconductor layers, and conductive layers formed on the substrate or the substrate itself may be etched.

A portion of the protrusion 22b of the second imprint material 22 remains on the semiconductor wafer W; and the semiconductor wafer W therebelow is not etched. A portion of the first imprint material 21 in the dicing region 5 also remains on the semiconductor wafer W; and the dicing region 5 is not etched.

As described above, the first pattern 23 of the first imprint material 21 is formed thinner than the protrusion 22b of the second imprint material 22. Accordingly, it is desirable for the first imprint material 21 to include a material having an etching resistance higher than that of the second imprint material 22 so that all of the first imprint material 21 is not undesirably consumed during the etching.

Even for a thin first imprint material 21, the consumption of the first imprint material 21 can be restricted to reliably leave the first imprint material 21 on the dicing region 5 by providing the first imprint material 21 with an etching rate slower than that of the second imprint material 22. Also, it is desirable to make the film thickness of the first pattern 23 of the first imprint material 21 thicker than the film thickness of the second imprint material 22 below the recess 22a of the second pattern 24 to reliably leave the first imprint material 21 on the dicing region 5.

FIG. 4E illustrates a state in which the first imprint material 21 and the second imprint material 22 remaining on the semiconductor wafer W are removed.

The pattern formation by the imprinting method using the first template 11 and the second template 12 described above is performed by a step-and-repeat method for each of the chips C. Alternatively, the first template for forming the first pattern in the dicing region may correspond to multiple chips.

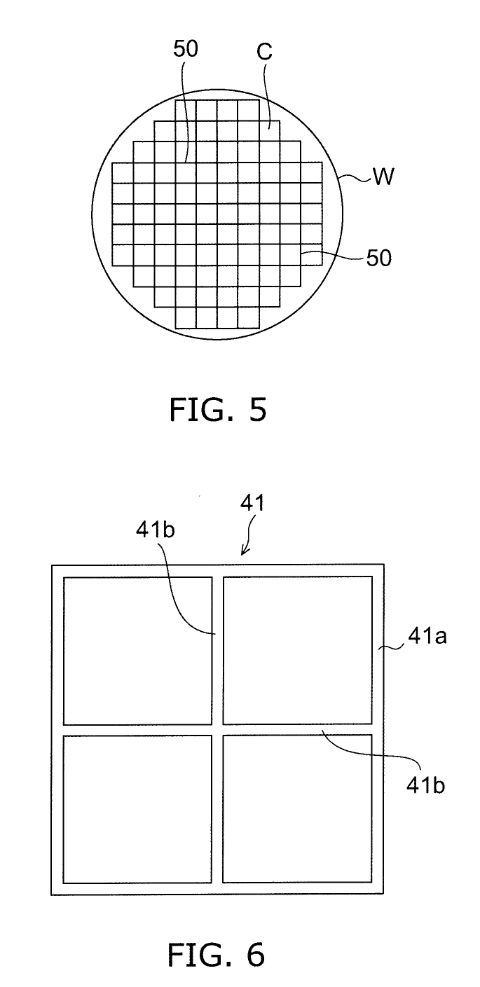

FIG. 6 illustrates a first template 41 including an outer frame 41a and an inner frame 41b surrounding, for example, four chips.

The first template forms the first pattern to cover the dicing region so that the dicing region is not etched during the etching of the chip region. Accordingly, positional precision and dimensional precision are not required as much as those of an ultra-fine pattern formed in the chip region. Therefore, it is possible to collectively form the first pattern surrounding multiple chips. Thereby, the throughput can be improved.

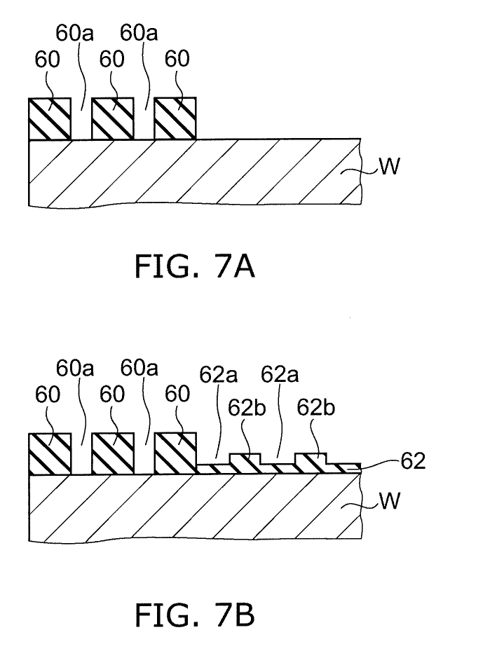

A comparative example for this embodiment will now be described with reference to FIGS. 7A and 7B.

In this comparative example, a resist pattern formed of a resist 60 is formed beforehand in a chip outer circumferential region by photolithography and developing as illustrated in FIG. 7A. Subsequently, a pattern is formed in an imprint material 62 in the chip region as illustrated in FIG. 7B by an imprinting method using a template. The imprint material 62 has a recess 62a and a protrusion 62b. The semiconductor wafer W surface below the recess 62a is patterned by etching using the imprint material 62 as a mask.

In the case of this comparative example, there is a risk of the adhesion between the imprint material 62 and the chip region surface decreasing due to resist residue, moisture, etc., remaining on the chip region surface of the semiconductor wafer W, alteration of the surface state, etc., after the developing during the resist pattern formation. In the case where the adhesion decreases, the imprint material 62 undesirably peels easily from the wafer surface when peeling the template from the imprint material 62.

Further, the resist is resolved to the bottom portion thereof during the photolithography; and the bottom portion of an opening 60a of the resist pattern reaches the surface of the semiconductor wafer W. Accordingly, during the etching after FIG. 7B, over-etching occurs more at the wafer surface facing the opening 60a at the outer circumferential region than the wafer surface below the recess 62a of the imprint material 62 of the chip region; and there is a risk that the controllability of the wafer patterning amount may worsen.

Conversely, in this embodiment, patterns are formed in both the chip region and the outer circumferential region thereof (the dicing region) by an imprinting method using a template. Therefore, costs are lower than those of photolithography technology; and because developing is not performed, the adhesion between the imprint material and the wafer surface is not reduced; and the imprint material does not undesirably peel from the wafer surface when the template is peeled.

Hereinabove, exemplary embodiments of the invention are described with reference to specific examples. However, the invention is not limited thereto. Various modifications based on the spirit of the invention are possible.

1. A method for manufacturing a semiconductor apparatus, comprising:
supplying a first imprint material onto a dicing region surrounding each chip of a semiconductor wafer;
bringing a first template having a frame-like configuration into contact with the first imprint material and curing the first imprint material;
peeling the first template from the first imprint material to form a first pattern in the first imprint material after the curing of the first imprint material;
supplying a second imprint material onto a chip region of the semiconductor wafer on an inner side of the first pattern;
bringing a second template into contact with the second imprint material and curing the second imprint material;
peeling the second template from the second imprint material to form a second pattern in the second imprint material after the curing of the second imprint material;
etching the semiconductor wafer, the first imprint material having the first pattern and the second imprint material having the second pattern being used as a mask.

2. The method according to claim 1, wherein the first imprint material is formed thinner than the second imprint material.

3. The method according to claim 2, wherein the first imprint material has an etching rate slower than an etching rate of the second imprint material during the etching.

4. The method according to claim 1, wherein the first imprint material is cured by ultraviolet irradiation or heating.

5. The method according to claim 1, wherein the second imprint material is cured by ultraviolet irradiation or heating.

6. The method according to claim 1, wherein
the first template has a recess made in a frame-like configuration, and
the first pattern is formed in a protruding configuration.

7. The method according to claim 1, wherein
the second template has a recess and a protrusion, and
the second pattern is a recess/protrusion pattern.

8. The method according to claim 7, wherein a film thickness of the first pattern is thicker than a film thickness of a portion of the second pattern below the recess.

9. The method according to claim 1, wherein a portion of the first pattern remains on the dicing region during the etching.

10. An imprint template, comprising:
a first template having a frame-like pattern corresponding to a pattern of a dicing region surrounding each chip of a semiconductor wafer; and
a second template having an inverted pattern of a recess/protrusion pattern, the recess/protrusion pattern being formed in a chip region of the semiconductor wafer on an inner side of the dicing region.

11. The imprint template according to claim 10, wherein the frame-like pattern of the first template is formed in a recessed configuration.

12. The imprint template according to claim 10, wherein the first template includes an outer frame surrounding a region including a plurality of chips of the semiconductor wafer in a frame-like configuration and an inner frame provided on an inner side of the outer frame.
